(19) United States
(12) Patent Application Publication
(10) Pub. No.: US 2007/0287279 A1
(43) Pub. Date: Dec. 13, 2007

(54) METHODS OF FORMING SOLDER CONNECTIONS AND STRUCTURE THEREOF

(76) Inventors: Timothy H. Daubenspeck, Colchester, VT (US); Jeffrey P. Gambino, Westford, VT (US); Christopher D. Muzzy, Burlington, VT (US); Wolfgang Santer, Richmond, VT (US)

Correspondence Address: GREENBLUM & BERNSTEIN, P.L.C., 1950 ROLAND CLARK DRIVE, RESTON, VA, 20191, US

(21) Appl. No.: 11/422,988

(22) Filed: Jun. 8, 2006

(51) Int. Cl. H01L 21/44

(52) U.S. Cl. 438/612

(57) ABSTRACT

A method for forming solder connections using dummy vias and the device. The dummy vias are formed prior to the application of ball limiting metals or solder material. After placing the under ball materials and the solder materials, the material covering the dummy vias has an increased surface contact and thus provide improved robustness and lifetime of the solder connection. Structures of implementation of the method are provided with either completely or partially filled dummy vias.

### FIELD OF THE INVENTION

The invention relates to methods of forming solder connections onto a semiconductor device and more particularly, methods of forming solder connections with increased surface area contact, eliminating undercut and cracking effects resulting in a more stable device, and a resulting device.

### BACKGROUND OF THE INVENTION

A solder connection on a semiconductor device includes several metal containing materials, including the solder bump itself which usually comprises low melting metal alloys or metal mixtures based on tin or lead. Less obvious are the materials underneath the solder bump which bridge the conductive connection between the solder bump and the first metallization contact that is formed at the back end of line processes of a semiconductor device. These under bump materials (UBM) are also referred to as the ball limiting metallurgical (BLM) layers, since they form the foundation of the solder bump and the solder material holds only at the area where the ball limiting metals are present.

In one conventional method, a refractory laminate of sputtered BLM films is wet etched after C4 (controlled collapse chip connection) process using the C4 as the etch mask. For lead free (Pb-free) or lead reduced (Pb-reduced) processing, the top layer of the BLM typically comprises copper or copper and an additional barrier film such as nickel (or nickel alloy), the barrier layer typically being electroplated. In the case for which the top layer is copper, the copper reacts with the tin based solder material to form an intermetallic CuSn barrier layer which is important to the reliability of the Pb-free or Pb-reduced C4 bump. In the case of copper and barrier material (e.g. Ni or Nix) the barrier prevents interdiffusion of Sn and Cu, while the Cu serves as a conductive layer to enhance electroplating of Ni.

When the copper and underlying films are wet-etched (using the solder bump and/or or the Ni barrier layer as etch mask), there rises the problem of under bump removal or undercut. This wet etch undercut is variable, and has the effect of reducing the BLM footprint at the joining interface between BLM and C4. This under bump removal can reach dimensions of up to 10 μm of lateral lost space intended for metal contacts. This, in turn, reduces the potential integrity of bump attachment.

As semiconductor devices become smaller, a need for smaller solder connection is also required. In such case, as the C4 pitch becomes smaller, process control becomes even more critical with respect to the reliability and utility of the final C4 structure since a relatively consistent undercut per edge represents a greater threat to the integrity of the final overall C4 structure. Also, it should be understood that as semiconductor devices become smaller, a point is reached where a 10 μm undercut is not acceptable and will significantly degrade device performance and reliability.

Accordingly, there exists a need in the art to overcome the deficiencies and limitations described hereinabove.

### SUMMARY OF THE INVENTION

In a first aspect of the invention, a method for forming a solder connection is provided. The method includes forming a structure with a metalized area and a barrier layer having an opening for connecting the metalized area to an overlying metal layer. The method further includes patterning at least one well and at least one dummy via into a passivation layer. The at least one dummy via is remote from the at least one well and is configured to increase a surface contact area. The method further comprises forming an opening in a resist layer over the at least one well and the at least one dummy via, and forming a ball limiting metallurgical (BLM) layer in the at least one well and the at least one dummy via. Solder material is provided over the BLM layer within the at least one well and the at least one dummy vias.

In a second aspect of the invention, a method includes forming a passivated layer with dummy vias on at least one side of a well positioned over at least one metallized layer in a structure. The method further includes forming a BLM layer in the dummy vias and the well and placing solder material over the BLM layer. The solder material is flowed to form a solder bump of solder material. The dummy vias increase a surface contact area for the solder material.

In an aspect of the invention, a controlled collapse chip connection (C4) structure is provided. The structure includes one or more dummy vias adjacent to the well of the solder connection. The dummy vias intercept stress related to cracks and prevent solder connection disruptions.

In another aspect of the invention, a semiconductor structure including a solder bump is provided. The solder bump has incorporated BLM material over a metallized structure that includes a dummy via. The dummy via has side walls and increase the surface contact area of the BLM material. The BLM material is at least partially formed in the dummy via.

### BRIEF DESCRIPTION OF THE DRAWINGS

FIGS. 1-6 show processing steps in accordance with an embodiment of the invention;

FIGS. 7-11 show processing steps in accordance with an embodiment of the invention; and

FIGS. 12-17 show processing steps in accordance with an embodiment of the invention.

### DETAILED DESCRIPTION OF EMBODIMENTS OF THE INVENTION

The invention relates to methods for forming solder connections on a semiconductor device. In embodiments, the methods of the invention reduce, if not entirely eliminates, corrosion or undercut of underlying layers of the solder connection. The present invention further increases surface area contract between the structure and the solder material, while eliminating or substantially reducing the effects of cracking or the propagation of cracks. In this manner, the solder bump prepared by the present method supports an increased device lifetime and performance.

In embodiments, the invention is a controlled collapse chip connection (C4) structure comprising a plurality of dummy vias adjacent to the well for a solder connection of a C4 structure. The plurality of dummy vias intercept stress related cracks to prevent solder connection disruptions.

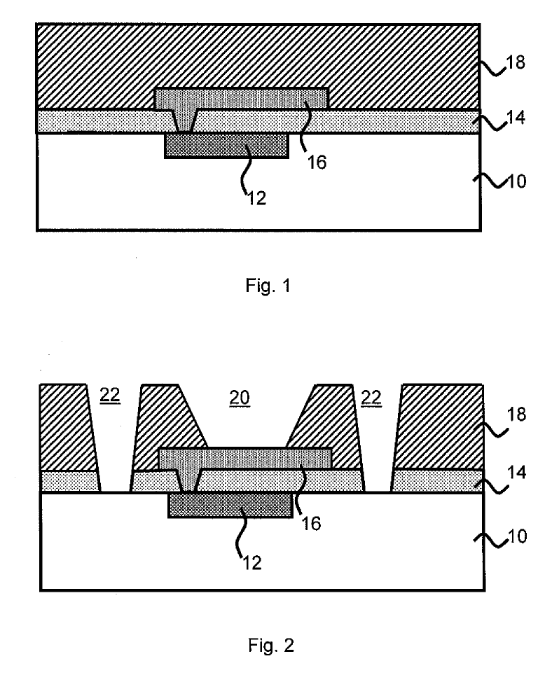

FIG. 1 represents a beginning structure at the back-end-of-line process level. The structure includes a metallization layer 12 on a semiconductor structure 10. The layer 10 comprises mostly non-conductive material such as silicon oxide or silicon nitride and can be of any desired thickness. The metallization layer 12 comprises any metal containing material or pure metal, such as and not limited to, copper or aluminum. The metallization layer 12 also represents the desired location of the solder connection on the semiconductor structure; although, it should be understood that other locations of solder connections are contemplated by the invention. For example, the metallization layer 12 can be a connection which leads to a semiconductor gate within the layer 10. Although not shown, a liner may be provided underneath the layer 12.

Still referring to FIG. 1, a passivated barrier layer 14 is provided on the layer 10 and metallization layer 12, which can be prepared by any conventional method. It should be understood by those of skill in the art that the layer 14 can comprise several layers of different materials having the same function. For example and without limitation to the scope of the invention, layer 14 can be built from silicon oxide and silicon nitride or alternative materials. In embodiments, the layer 14 has a thickness of about 1 μm; however, other thicknesses are contemplated by the present invention. The layer 14 also includes an opening to the metallization layer 12, which allows a metallization layer 16, e.g., aluminum, to contact with the metallization layer 12.

The structure is covered by a polyimide layer 18 which further passivates the structure. The layer 18 has a thickness of approximately 4 to 5 μm; although, other thicknesses are contemplated by the invention. In embodiments, the total thickness of the materials applied to the layer 10 has a total thickness between 5 to 6 μm.

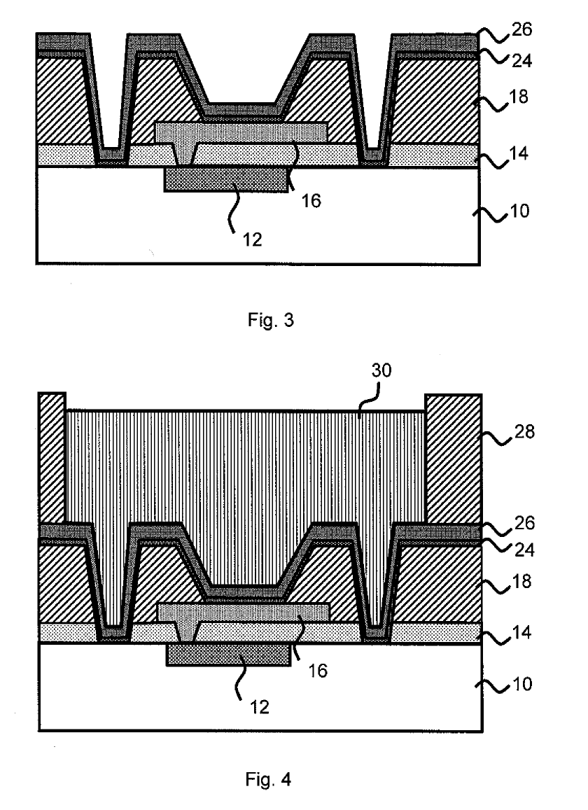

FIG. 2 depicts the device or wafer after further processing. In this processing step, vias 20 and 22 are etched into the structure. In embodiments, the vias 22 are etched into layers 14 and 18; whereas, the via 20 is etched to the metal layer 16, forming an opening to the metal layer 16. The via 20 is referred to as the electrical well and will be used to form the basis for the central location of the solder bump. The via 20 may be of any conventional dimension for solder connection such as, for example, having a base dimension of up to 50 μm. However, in view of further applicability of this method and structure, smaller dimensions are contemplated by the present invention.

The vias 22 are provided to increase the surface area for a solder connection which, in turn, will increase the robustness of the device. The vias, in embodiments, will not be used to make solder connection to the metal layer 16 and are thus termed dummy vias 22. The dummy vias 22 have steep sidewalls which will allow for a greater contact area between the solder bump and surface of the structure, without having to greatly increase the overall width of the final device.

In embodiments, the dummy vias 22 comprise a base diameter of about 3 to 5 μm and are etched into the layers 14 and 18 at a steep angle between 60 and close to but not exceeding 90 degrees. The steep angle also serves as an etch barrier to prevent undercut in the lower layers and to eliminate or substantially reduce cracking, the propagation of cracks and/or the effects thereof.

FIG. 3 represents the device after layering of the BLM materials. In embodiments, layers 24 and 26 are formed over the structure, including within the via 20 and the dummy vias 22. The BLM material can include any conventional material such as, for example, titanium, titanium tungsten alloys, copper and copper chromium alloys. The combined thickness of layers 24 and 26 is, in embodiments, between 1 and about 3 μm. In more specific embodiments, the layer 24 is preferably between 0.1 and 1 μm, more preferably between 0.2 and 0.8 μm and most preferably about 0.6 μm. The layer 26 is, in embodiments, between 0.5 and 3 μm, more preferably 1 and 2 μm and most preferably between 1.5 and 1.8 μm.

It should be understood that the BLM layers can be prepared by any conventional method, e.g., layer 24 can be prepared by sputtering or PVD followed by an electroplating process to form layer 26. Furthermore, the layers are prepared in blanket fashion; however localized preparation on the wafer is contemplated by the invention.

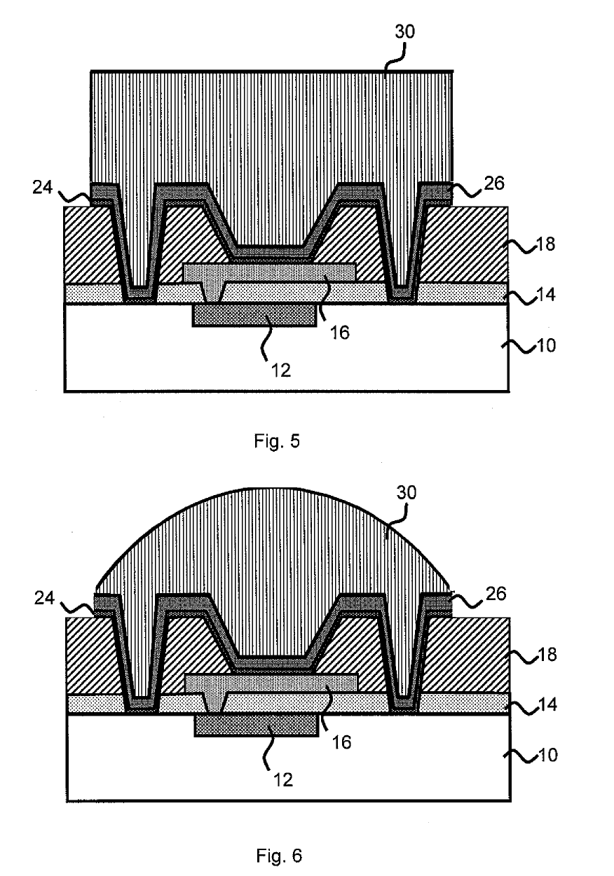

Referring to FIG. 4, a resist pattern 28 is applied onto layer 26. In embodiments, an opening is formed in the resist pattern 28, and in embodiments, such opening is provided coincident with the via 20 and the dummy vias 22, for the application of solder material 30. In embodiments, the resist has a thickness between 3 to 5 μm depending on the desired height of the solder material.

In embodiments, the solder material remains within the resist pattern. The solder material 30 comprises any conventional material, such as lead free or lead reduced tin based material. Furthermore, the material can be applied by any known method. For example and without limiting the scope of the invention, the material can be applied by a flow process, i.e., molten solder material is filled into the well confined by the described elements and the resist pattern. Alternatively, the material can be applied by a physical transfer C4 bump process, where a form-fitting solder piece has been prepared in a parallel process and is placed onto the wafer or semiconductor device.

In FIG. 5, the resist pattern is stripped and the uncovered portions of layers 24 and 26 have been etched. In this embodiment, the solder material 30 serves as a mask for the etching process and thus protects portions of the underlying layers. As shown in FIG. 5, the solder material is applied in the dummy vias 22 thus increasing the surface area contact of the solder material, while not significantly increasing the size of the device. This increased surface in the connection provides for a more robust solder connection.

In embodiments, any conventional etching method can be used to etch exposed layers 24, 26. For example, an anisotropic etching can be used to etch the layers 24 and 26. If an anisotropic etching method such as RIE is used, the layers 24 and 26 are etched substantially flush with the solder material 30 thus not forming any undercut. If an isotropic etching method, such as wet etching is used, then portions of layers 24 and 26 underneath solder 30 are subject to the wet etching process, thereby resulting in some undercut. However, this undercut does not significantly affect the overall connection due to (i) the increased surface area contact of the solder and (ii) the change of the course of undercut underneath the solder.

The presence of the steep downward angle of layers 24 and 26 caused by the dummy vias 22 sets a limit to the undercut dimension. In essence, the angular changes of layers 24 and 26 act as an undercut “interrupt”. Thus, although technically layers 24 and 26 are etched, any corrosion of layers 24 and 26 (by about 10 μm) ends at some point of the steep downward portion on the sidewall of dummy vias 22 causing little or no reduction to the structural stability of the solder connection.

FIG. 6 depicts the solder bump after the reflow process. If the previous etching step was anisotropic, the bump spans its original size at its base and completely fills the dummy vias 22. If however, the etching process was isotropic and undercut occurred, then the bump would span from one outside wall of the dummy via across the via 20 to the other side of the outside wall of the dummy vias 22 without a substantial loss of stability.

Furthermore, as can be seen in FIG. 6, the ratio of BLM surface in contact with the solder material is significantly increased due to the presence of the dummy vias 22. This greater contact area reduces the effects of solder bump stability previously caused by cracking or propagation of cracks. In this manner, the solder bump prepared by the present method supports an increased device lifetime and performance. Also, the structure of the solder bump depicted by the filled dummy vias 22 increases the robustness of the final solder connection which then becomes less susceptible towards outside shear forces.

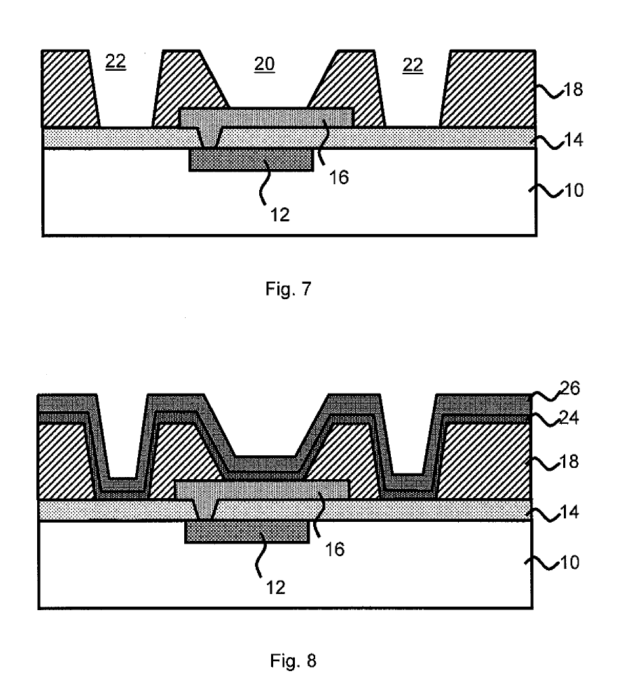

FIG. 7 shows the beginning structure in accordance with another aspect of the invention. In this embodiment, the structure is formed by the same processes as described in reference to FIGS. 1 and 2, except that the dummy vias 22 are now etched into the layer 18 and stop at the passivation layer 14. Omitting the etching of passivation layer 14 saves process time.

In embodiments, the dummy vias 22 are kept a little wider than previously shown and can thus be filled with more material, as described herein. Without limiting the scope of the invention, a via diameter of 4 μm is preferred; however, other widths are contemplated as well. The angle of 60 to 80 degrees is kept unchanged.

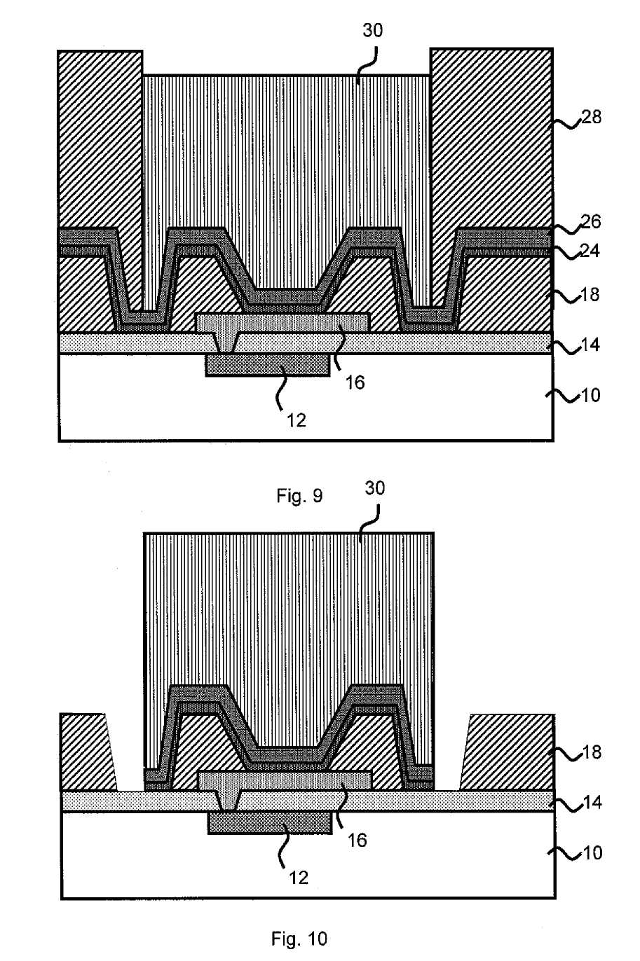

FIG. 8 shows the formation of layers 24 and 26 applied by the same method and with the same materials as described for FIG. 3, e.g., sputtering of a titanium tungsten layer 24 followed by an electroplating process of a copper or copper chromium layer 26.

FIG. 9 shows the structure after the dummy vias 22 have been filled partially with solder material 30 and partially with resist 28. Although FIG. 9 appears to show a 1:1 distribution of the two materials in the dummy vias 22, any other ratio is contemplated by the invention. For example, the dummy vias 22 can be filled to 90% by the solder material and the remainder by the resist or vice versa.

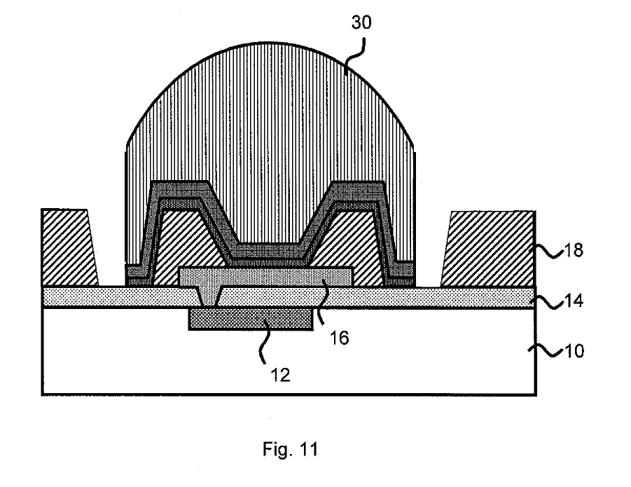

FIG. 10 shows the structure after stripping/etching, e.g., after removal of the resist and etching of unmasked layers 24 and 26. Again, if an anisotropic etching process is chosen, then there will be no undercut in the underlying layers. However, in the case of isotropic wet etching, undercut will occur. But, similar to the process where the undercut is stopped at the downward portion of layers 24 and 26, in this embodiment the undercut would be limited to the upward portion of the two layers within the dummy vias 22. However, this will not substantially affect the overall robustness of the solder connection in view of the increased surface area of the solder connection.

FIG. 11 shows the solder bump after reflow. In this embodiment, the bump spans its original size at its base and partially fills the dummy vias 22. Furthermore, the increased contact area reduces the effects of solder bump stability previously caused by cracking or propagation of cracks. In this manner, the solder bump prepared by the present method supports an increased device lifetime and performance. Also, the use of the vias 22 increases the robustness of the final solder connection which then becomes less susceptible towards outside shear forces. Moreover, any undercut will not substantially affect the solder connection.

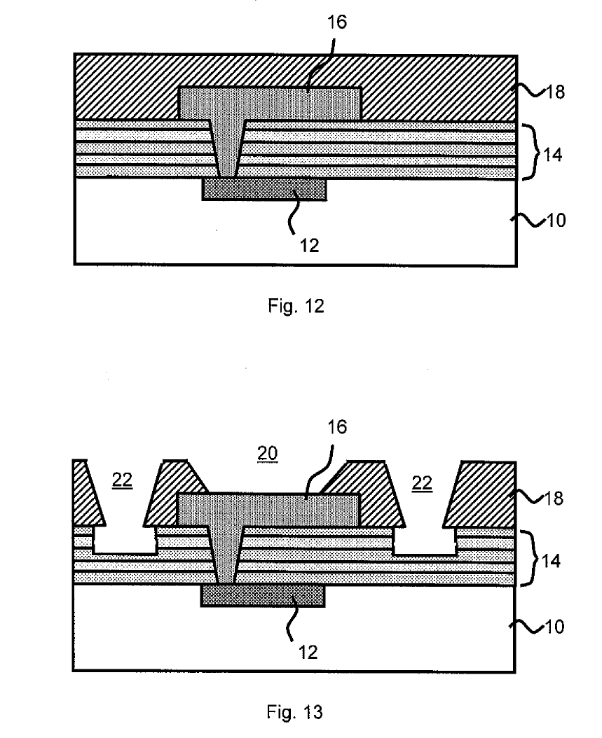

FIG. 12 shows a beginning structure in accordance with another embodiment of the invention. In this embodiment, the layer 14 shows an optional build-up of several layers, e.g., silicon oxide, silicon nitride, etc.

Referring to FIG. 13, the via (electrical well) 20 and dummy vias 22 are etched into layer 18 according to the processes described in reference to FIG. 2. However, in this embodiment, the layer 14 has not been entirely etched through forming an undercut or groove underneath layer 18. In one embodiment, the etching of a silicon oxide based element 14 without harming the layer 18 can be achieved by the use of hydrogen fluoride in any known medium, e.g., in solution or as a gas, in the presence or absence of buffering substances. In the case of one layer of layers 14 being a silicon nitride layer, a nitride wet etch can be used to afford the desired widened via. The widened via is used, in embodiments, to create an interrupt in the BLM layers across the semiconductor device or wafer

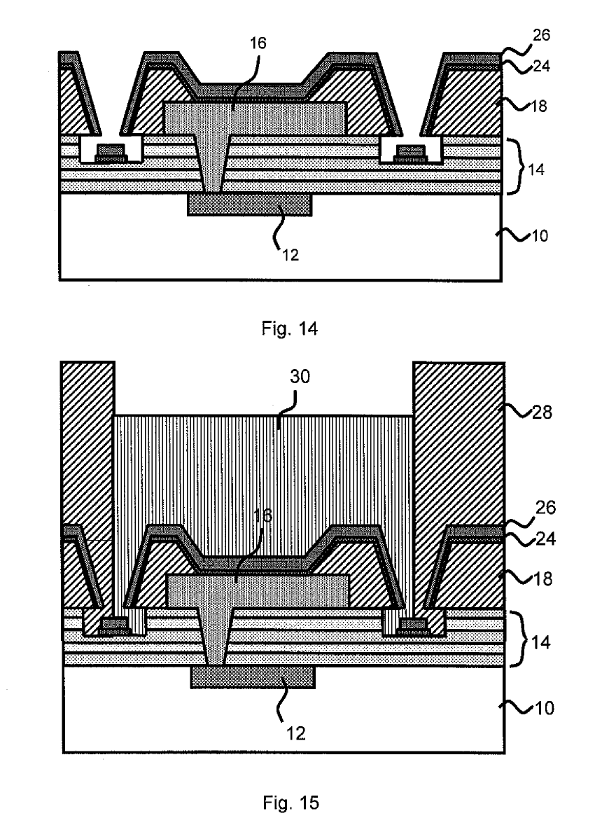

FIG. 14 shows the structure after layers 24 and 26 have been applied according to the processes described above. As now can be seen, the widened area underneath the dummy vias 22 are not lined by layers 24 and 26. Thus an interrupt in the layers 24 and 26 is created.

FIG. 15 shows the structure with resist 28 and solder material 30. In analogy to FIG. 9, the materials 28 and 30 fill portions of the dummy vias, and in this embodiment, the widened via in layer 14. As seen in FIG. 15, the layers 24 and 26 are interrupted or spaced apart, with the material 28 and 30 formed in such spaces. Here again, any ratio of the distribution of the two materials is conceivable, but it is preferred that all of the portions of layers 24 and 26 between the via 20 and the interrupt in the dummy vias 22 is covered by solder material.

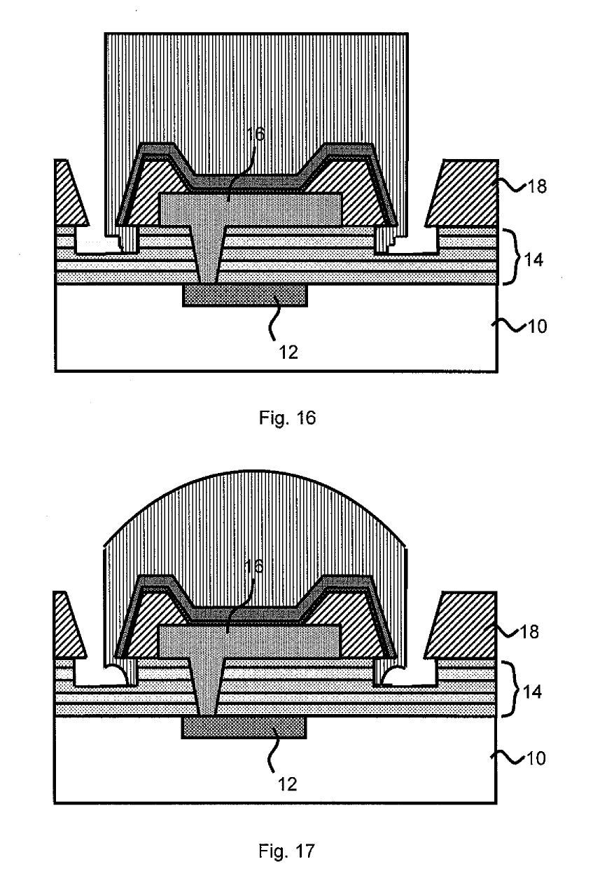

FIG. 16 shows the device after removal of the resist 28 and etching the unprotected portions of layers 24 and 26. As now can be seen, the etching process is limited to a designed point, since portions of layers 24 and 26 are completely enclosed by solder material and thus protected from etching. The solder material 30 further incorporates some BLM material and protects some portions of layers 24 and 26 during the etching process, thus preventing any undercut. Again, using the via dummies, an increase in the surface area for solder bump connection is provided. Also, the attenuation or propagation of cracks is reduced. FIG. 17 shows the solder bump after the reflow process and depicts the finished semiconductor structure with solder connection, whereby the BLM material is incorporated into the solder bump.

While the invention has been described in terms of embodiments, those skilled in the art will recognize that the invention can be practiced with the modification within the spirit and scope of the appended claims. For example, the invention can be readily applicable to bulk substrates.

What is claimed is:

1. A method comprising:
forming a structure with a metallized area and a barrier layer having an opening for connecting the metallized area to an overlying metal layer;
patterning at least one well and at least one dummy via into a passivation layer, the at least one dummy via being remote from the at least one well and increasing a surface contact area;
forming an opening in a resist layer over the at least one well and the at least one dummy via;
forming a ball limiting metallurgical (BLM) layer in the at least one well and the at least one dummy via; and
providing solder material over the BLM layer within the at least one well and the at least one dummy via.

2. The method according to claim 1, wherein the patterning of the at least one dummy via is in the barrier layer.

3. The method according to claim 1, wherein the patterning of the at least one dummy via is stopped at the barrier layer.

4. The method according to claim 1, wherein the solder material is provided only in a portion of the at least one dummy via.

5. The method according to claim 1, wherein the patterning of the at least one dummy via forms an undercut in the barrier layer under the passivation layer, and the BLM layer has an interrupt or space within at least one dummy via.

6. The method according to claim 5, wherein the solder material is provided only in a portion of the at least one dummy via.

7. The method according to claim 5, wherein the solder material and resist are provided within the interrupt of space at the undercut.

8. The method according to claim 1, wherein the at least one dummy via has an angled wall of approximately 60 to close to, but not exceeding 90 degrees.

9. The method according to claim 1, wherein the BLM layer is contacting the overlying metal layer and is at least partially formed by electroplating.

10. The method according to claim 1, wherein the passivation layer comprises polyimide and the barrier layer comprises at least one of silicon oxide and silicon nitride.

11. The method according to claim 1, wherein a longitudinal dimension of the solder bump extends to outer sidewalls of the at least one dummy via.

12. The method according to claim 1, wherein the solder material is used as a mask during an etching step.

13. The method according to claim 1, wherein the solder material comprises lead free tin containing material or lead reduced tin containing material.

14. A method for increasing contact surface area of a solder connection comprising:
forming a passivated layer with dummy vias on at least one side of a well positioned over at least one metallized layer in a structure;
forming a BLM layer in the dummy vias and the well;
flowing solder material over the BLM layer to form a solder bump of solder material,
wherein the dummy vias increase a surface contact area for the solder material.

15. The method according to claim 14, wherein one of the dummy vias are formed in a barrier layer, extending to an underlying substrate;
the dummy vias are formed to a barrier layer; and
the dummy vias are formed in the barrier layer and have an undercut region under the passivated layer.

16. The method according to claim 14, wherein the solder material is formed only partially within the dummy vias.

17. The method according to claim 14, wherein the dummy vias are formed in the barrier layer and have an undercut region, the BLM layer has an interrupt within the dummy regions and the solder material is at least partially within the interrupt acting as a mask to prevent undercut in a subsequent etching process.

18. A controlled collapse chip connection (C4) structure comprising a plurality of dummy vias having a metallization scheme adjacent to a well for a solder connection of a C4 structure, the plurality of dummy vias intercepting stress related cracks to prevent solder connection disruptions.

19. The structure of claim 18, wherein the plurality of vias include walls of angles between approximately 60 and close to but not exceeding 90 degrees and wherein the metallization scheme includes Cu-termination scheme or Ni-barrier termination scheme.

20. A semiconductor structure comprising a solder bump with an incorporated BLM material over a metallized structure comprising at least one dummy via having side walls which increase a surface contact area between the incorporated BLM material and the metallized structure, wherein the incorporated BLM material is formed at least partially in the at least one dummy via.
